(19) United States
(12) Patent Application Publication
(10) Pub. No.: US 2012/0161182 A1
(43) Pub. Date: Jun. 28, 2012

(54) DISPLAY DEVICE

(75) Inventor: Kiyokatsu Ikemoto, Yokohama-shi (JP)

(73) Assignee: CANON KABUSHIKI KAISHA, Tokyo (JP)

(21) Appl. No.: 13/333,874

(22) Filed: Dec. 21, 2011

(30) Foreign Application Priority Data
Dec. 27, 2010 (JP) 2010-290329

(51) Int. Cl. H01L 33/58

(52) U.S. Cl. 257/98; 257/E33.074

(57) ABSTRACT

Provided is a display device which includes a front plate, a light emitting layer, a scattering layer and an excitation source. The front plate is formed by medium which is transparent to light of a wavelength in a visible range. An excitation source has a mechanism to excite a light emitting layer. The light emitting layer includes a light emitting medium. A scattering layer is provided on the back side of the light emitting layer which scatters at least a part of light produced by the light emitting layer and has an effective refractive index higher than that of the light emitting layer.

### BACKGROUND OF THE INVENTION

1. Field of the Invention

The present invention relates to a high contrast display device.

2. Description of the Related Art

Display devices of various configurations have been proposed. U.S. Pat. No. 6,476,550 (hereinafter “Patent Document 1”) describes a display device of which configuration is illustrated, in a sectional view, in FIG. 9. A display device 1100 illustrated in FIG. 9 includes a front plate 1001, light emitting layer 1002, a transparent electrode 1003 and a metal electrode 1004. Light is produced when the light emitting layer 1002 is supplied with electrons and positive holes by the transparent electrode 1003 and the metal electrode 1004. A part of the produced light is extracted outside and provides display light 1005. It has been found that, among all the light produced in the light emitting layer 1002, a part of the light 1006 oriented to a back side (i.e., a minus direction of the z axis) is reflected by the metal electrode 1004 toward a side on which the light is transmitted (i.e., a plus direction of the z axis) and, as a result, brightness of display light 1005 is increased. A ratio of light which is output outside and provides display light among all the light produced in the light emitting layer is called light extraction efficiency.

U.S. Pat. No. 6,844,667 (hereinafter “Patent Document 2”) describes a configuration, which is similar to the display device 1000 illustrated in FIG. 10, including an electron source 1007 which excites a light emitting layer 1002, and a metal electrode 1004 disposed on the back side of the light emitting layer 1002. Application of an electric field to the electron source causes electron emission: the emitted electrons pass through the metal electrode 1004 and supplied to the light emitting layer 1002 to thereby produce light. Among all the light produced in the light emitting layer 1002, a part of the light 1006 oriented to a back side is reflected by the metal electrode 1004 toward a side on which the light is transmitted and, as a result, brightness of display light is increased similarly to the display device 1000.

Reflectance of light entering from the outside to the display device is called external light reflectance.

In the proposed display devices 1000 and 1100 illustrated in FIGS. 9 and 10, a part of external light 1008 which enters the display devices 1000 and 1100 transmits the front plate 1001 and the light emitting layer 1002 and is strongly reflected by the metal electrode 1004 to thereby provide reflected light 1009. Therefore, the external light reflectance increases and the contrast decreases.

In the display device 1100, a part of energy of electrons emitted from the electron source 1007 is absorbed when the electrons pass the metal electrode 1004. Such absorption of electrons lowers efficiency of the exciting the light emitting layer 1002, reduces an amount of produced light and decreases brightness of the display light 1005. Thus, display light of the display device 1100 is low and, as a result, the display device 1100 has low contrast.

### SUMMARY OF THE INVENTION

The present invention provides a display device with increased display light brightness (“display brightness”), decreased external light reflectance and high contrast.

The present invention is a display device which includes: a substrate; a light emitting layer disposed on the substrate; and a scattering layer which is disposed on the substrate via the light emitting layer to face the substrate and scatters at least a part of light produced by the light emitting layer, wherein: an effective refractive index of the light emitting layer is higher than a refractive index of an area which a surface of the scattering layer opposite to the surface which faces the substrate is in contact with; and an effective refractive index of the scattering layer is higher than the effective refractive index of the light emitting layer.

The present invention provides a high contrast display device.

Further features according to the present invention will become apparent from the following description of exemplary embodiments with reference to the attached drawings.

### BRIEF DESCRIPTION OF THE DRAWINGS

FIG. 1 illustrates, in an xz sectional view, an example of a display device and light produced in a light emitting layer according to the present invention.

FIG. 2 illustrates, in an xz sectional view, an example of a display device and external light according to the present invention.

FIGS. 3A, 3B, and 3C are an example of manufacturing process of a display device according to the present invention.

FIGS. 4A, 4B, and 4C are an example of manufacturing process of a display device according to the present invention.

FIG. 5 is a graph representing a calculation result of light extraction efficiency of a display device according to the present invention.

FIG. 6 is a graph representing a calculation result of external light reflectance of a display device according to the present invention.

FIG. 7 is a graph representing a calculation result of light extraction efficiency of another example of the display device according to the present invention.

FIG. 8 is a graph representing a calculation result of external light reflectance of another example of the display device according to the present invention.

FIG. 9 illustrates, in an xz sectional view, an example of a related art display device.

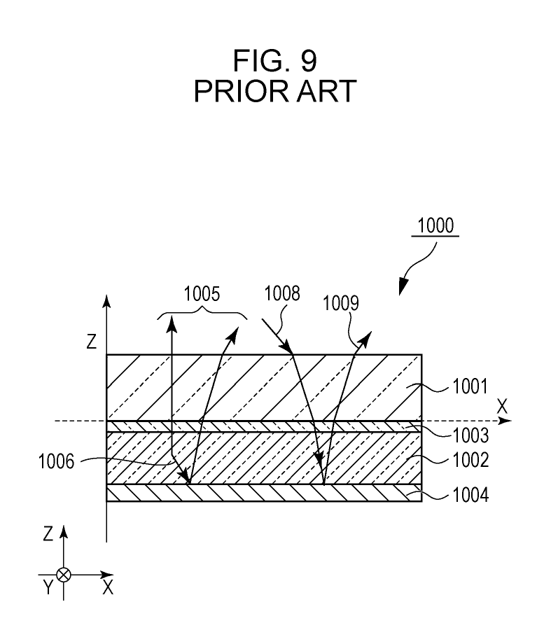

FIG. 10 illustrates, in an xz sectional view, another example of the related art display device.

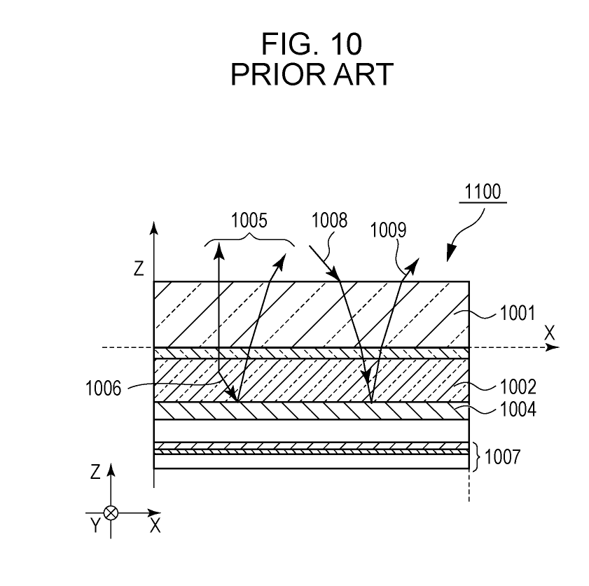

### DESCRIPTION OF THE EMBODIMENTS

Hereinafter, the present invention will be described in detail with reference to an embodiment.

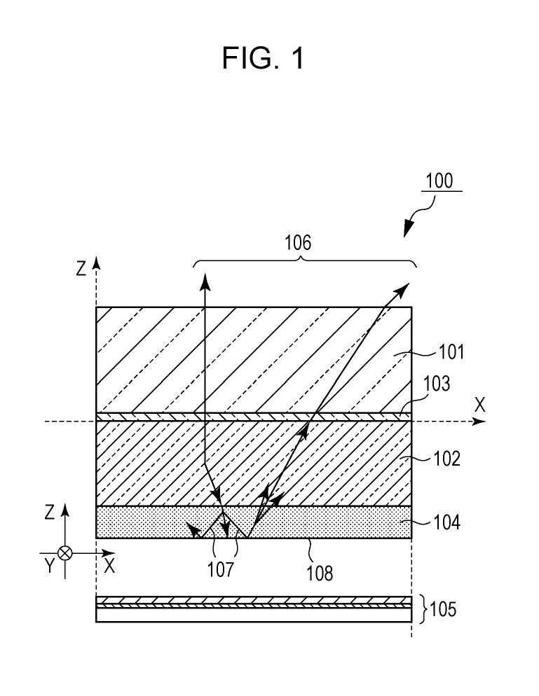

A display device according to an embodiment of the present invention is illustrated in FIG. 1, where a display device 100 is shown in an xz sectional view. The display device 100 includes a front plate 101 which is a substrate, a light emitting layer 102 disposed on the substrate, and a scattering layer 104 disposed on the front plate 101 so as to face the substrate via the light emitting layer. The scattering layer 104 scatters at least a part of light produced by the light emitting layer. In the present embodiment, an area which faces a back side of the scattering layer 104, i.e., a side opposite to the side on which the scattering layer 104 faces the front plate 101, is a vacuum area. An effective refractive index of the light emitting layer 102 is higher than a refractive index of this vacuum area. An effective refractive index of the scattering layer is higher than that of the light emitting layer 102. The display device 100 illustrated in FIG. 1 desirably includes a transparent electrode 103, as a part of an excitation source, between the front plate 101 and the light emitting layer 102. The display device 100 also includes an electron source 105, as a part of the excitation source, disposed to face the light emitting layer 102.

The front plate 101 is formed by a medium which is transparent to visible light, such as glass. The light emitting layer 102 is formed by a light emitting medium, such as phosphor, and produces light of a visible wavelength between 350 to 800 nm. The scattering layer 104 is desirably formed by a nonmetallic medium in which, for example, fine particulates are dispersed. The effective refractive index N_{eff} of the scattering layer 104 is determined by a refractive index of each medium, such as fine particles and the medium surrounding the fine particles which constitute the scattering layer 104, and a volume ratio between each of the media occupying the area. The effective refractive index N_{eff} is expressed by Equation 1.

N_{eff}=N1*ff1+N2*ff2 Equation (1)

In Equation 1, the refractive index of each medium (i.e., the real part of complex refractive index) is represented by N1 and N2 and the volume ratio each medium occupies the space is represented by ff1 and ff2. Similarly, the effective refractive index of the light emitting layer 102 is expressed by Equation 1 on the basis of the refractive index of the medium which constitutes the light emitting layer 102 and the volume ratio each medium occupies to space. The effective refractive index of the scattering layer 104 is higher than that of the light emitting layer 102. In the display device of such a configuration, application of an electric field to the electron source 105 causes electron emission. The emitted electrons are accelerated under high voltage applied to the transparent electrode 103 and then the light emitting layer 102 is irradiated with the electrons to thereby produce light. In this manner, display light 106 is obtained.

Next, the reason for which the high contrast display device is achieved in the present embodiment will be described. First, an increase in display light 106 will be described. In the display device 100 of the present embodiment, the effective refractive index of the scattering layer 104 is higher than that of the light emitting layer 102. Therefore, the critical angle on the back surface of the scattering layer 104 opposite to the surface facing the front plate 101 which is the substrate (i.e., a surface which faces the electron source 105) becomes smaller. As a result, among all the light produced in the light emitting layer 102, the amount of light transmitting the back side of the scattering layer 104 is reduced and thus the amount of total reflection light which returns to the light emitting layer 102 is increased. This will be described in full detail below. Hereinafter, the back surface of the scattering layer 104 opposite to the surface facing the front plate 101 which is the substrate (i.e., a surface which faces the electron source 105) will be called a last surface 108. An area which the last surface 108, which is the back side of the scattering layer 104, is in contact with will sometimes be called a back side area.

In a configuration which includes no scattering layer 104, the back side of the light emitting layer 102 (i.e., a surface which faces the electron source 105) will be considered as the last surface.

A part of the light 107 scattered by the scattering layer 104 among all the light produced in the light emitting layer 102 is reflected on the last surface 108 and oriented to the light extraction side (i.e., the side of the front plate 101) to provide display light. Reflectance of the last surface 108 is determined on the basis of the refractive index difference between the scattering layer 104 and the back side area (i.e., an area between the scattering layer 104 and the electron source 105, which is the vacuum area in the present embodiment), and the incident angle of light to the last surface 108. As the critical angle increases, the refractive index difference decreases. If the incidence angle is larger than the critical angle, the light is totally reflected. That is, a smaller critical angle increases the amount of total reflection light.

If the effective refractive index of the scattering layer 104 is higher than that of the light emitting layer 102, the refractive index difference between the last surface 108 and the back side area (which is the vacuum area in the present embodiment) increases as compared with a configuration which includes no scattering layer 104 and, therefore, the critical angle of the last surface 108 decreases. If the light is scattered by the scattering layer 104, the scattered light is converted into light propagating to various directions. If the light is scattered by the scattering layer 104, the light of larger incidence angle to the last surface 108 is increased and, therefore, the amount of total reflection light is increased. Suppose a configuration in which a layer that has the effective refractive index higher than that of the light emitting layer 102 but causes no scattering is provided instead of the scattering layer 104: light enters from a low refractive index medium to a high refractive index medium and is refracted: therefore, the incidence angle to the last surface 108 decreases and thus the amount of total reflection light does not increase. Further, suppose a configuration in which a layer that scatters light and has the effective refractive index lower than that of the light emitting layer 102 is provided instead of the light scattering layer 104: in this case, although the light is scattered and light with larger incidence angle to the last surface 108 increases, the critical angle of the last surface 108 increases or becomes equal to that of the light emitting layer 102; therefore, the amount of total reflection light decreases or is unchanged.

As described above, the scattering layer 104 of the present embodiment increases the amount of reflected light and the amount of the display light 106 emitted outside. If at least a part of the light produced from the light emitting medium is scattered by the scattering layer 104, the amount of the display light 106 increases as compared with a configuration which includes no scattering layer 104. This effect is enhanced if, desirably, 1% or more of the light among all the light entered the scattering layer 104 is scattered. Brightness of the display light 106 is enhanced if, more desirably, 5% or more and, even more desirably, 10% or more of the light is scattered.

Among all the light propagating through the light emitting layer 102 and the front plate 101, the light which enters an interface between the light emitting layer 102 and the transparent electrode 103 or an interface between the front plate 101 and an external area at an angle equal to or larger than the critical angle is totally reflected. In the configuration of the present embodiment, the light is scattered and reflected by the scattering layer 104 and is converted into light oriented to the front plate 101 again; then the light is emitted outside to provide the display light 106. With this effect, brightness of the display light 106 is further enhanced.

In the above description, the area which the back side of the scattering layer 104 is in contact with is a vacuum area, but this is not restrictive; this area may be, for example, air as long as it has the refractive index lower than that of the light emitting layer 102.

Next, a reduction in external light reflection will be described. If external light enters the display device 100, a part of the external light reaches and is scattered by the scattering layer 104. Among all the scattered light, the light which enters an interface between the front plate 101 and the outside or an interface between the light emitting layer 102 and the transparent electrode 103 at an angle equal to or larger than the critical angle is totally reflected. Thus, only a part of the scattered light becomes the external reflection light. Therefore, it is possible to reduce the external light reflection as compared with a related art configuration. A part of light scattered by the scattering layer 104 and the light reflected by an interface between the light emitting layer 102 and the scattering layer 104 and by the last surface 108 becomes the external reflection light. The reflectance of each interface is determined by a refractive index difference between the interfaces. In a configuration in which the scattering layer 104 is formed by a nonmetallic member, such as a common dielectric medium and a semiconductor medium, the reflectance of each interface is substantially reduced as compared with the reflectance of a metal film in the related art configuration; therefore, the external reflection light is further reduced.

As described above, in the display device 100 of the embodiment of the present invention, a high contrast display device with low external light reflectance and high display light brightness is obtained.

The light emitting layer 102 and the scattering layer 104 included in the embodiment of the present invention are not restricted to those illustrated in FIG. 1. For example, the scattering layer 104 may be formed by a light emitting material similarly to the light emitting layer 102. If the scattering layer 104 is formed by a light emitting material, the scattering layer 104 also produces light. Therefore, the amount of emitted light increases and the maximum brightness becomes high.

The light emitting layer 102 and the scattering layer 104 may be formed by a medium and fine particles dispersed therein. If both the light emitting layer 102 and the scattering layer 104 are formed by a medium and fine particles dispersed therein, it is desirable that the filling rate of the fine particles to the medium in the light emitting layer is different from the filling rate of the fine particles to the medium in the scattering layer. It is desirable that the medium and the fine particles in the light emitting layer are the same as those of the scattering layer. If the refractive index of the fine particles is higher than that of the medium surrounding the fine particles, for example, the effective refractive index of the scattering layer 104 becomes higher than that of the light emitting layer 102 in a configuration in which the filling rate of the fine particles in the scattering layer 104 is higher than that of the light emitting layer 102. In such a configuration, it is possible to manufacture the light emitting layer 102 and the scattering layer 104 from the same material under the same manufacturing method in different manufacturing processes. The light emitting layer 102 may have scatterability. If light emitting layer 102 has scatterability, light is totally reflected by each of the interfaces and the light entrapped inside the light emitting layer 102 is scattered. As a result, the scattered light is easily converted into light oriented in different directions and thus easily converted into the display light 106. The diameter of the fine particles is desirably equal to or smaller than the wavelength of visible light, more desirably equal to or smaller than ½ of the wavelength of visible light and even more desirably equal to or smaller than ⅕ of the wavelength of visible light. As will be described in detail below, if the diameter of the fine particles is in this range, the scatterability becomes close to the Mie scattering and therefore the orientation intensity distribution may become close to the uniform distribution.

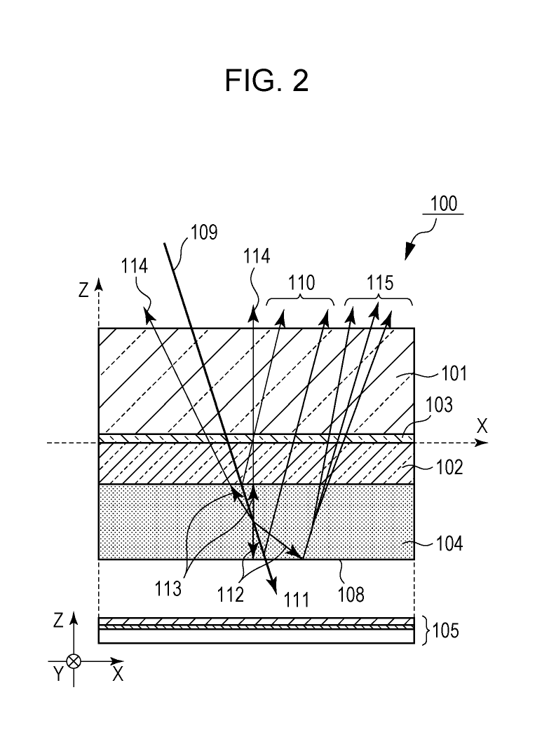

FIG. 2 illustrates the display device 100 in an xz sectional view. The scattering layer 104 desirably has a configuration in which, with respect to light 109 which enters at an angle equal to or smaller than the critical angle of the last surface 108, the intensity of nonscattering reflected light 110 is lower than the sum of the intensity of nonscattering transmission light 111 and the intensity of scattered light 112 and 113. That is, the scattering layer 104 desirably has a configuration in which, among all the light which enters the scattering layer at an angle equal to or smaller than the critical angle on the back surface of the scattering layer 104 opposite to the surface facing the front plate 101 which is the substrate, the intensity of the light which is not scattered by the scattering layer but is reflected toward the substrate is lower than the sum of the intensity of light which is not scattered by the scattering layer but transmitted by the scattering layer and the intensity of light scattered by the scattering layer. Here, the scattered light 112 and 113 designates the light scattered by the scattering layer 104 as illustrated in FIG. 2. The nonscattering reflected light 110 designates the light which is reflected on an interface between the scattering layer 104 and the light emitting layer 102 and the interface between the scattering layer 104 and the back side area (i.e., an area which the back surface of the scattering layer 104 opposite to the surface facing the front plate 101 which is the substrate is in contact with) and becomes external reflection light. The nonscattering transmission light 111 designates the light which is not scattered by the scattering layer 104 but transmits toward the back side area (i.e., an area which the back surface of the scattering layer 104 opposite to the surface facing the front plate 101 which is the substrate is in contact with). The external light 109 is refracted on each of the interfaces and is propagated inside the scattering layer 104 at an angle equal to or smaller than the critical angle of the last surface 108. The external light 109 is distributed by the scattering layer 104 to the scattered light 112 and 113, the nonscattering reflected light 110, and the nonscattering transmission light 111. Among these distributed light, the nonscattering reflected light 110 reflected to the outside is a factor of disturbed watching because it causes surrounding lighting and images to appear on the display device. The scatterability of the scattering layer 104 is controllable depending on the thickness of the scattering layer 104, the diameter and density of the fine particles, and the medium forming the scattering layer 104. Appearance of light in the display device can be reduced by controlling the scatterability of the scattering layer 104 and lowering the intensity of the nonscattering reflected light 110 to below the sum of the intensity of the nonscattering transmission light 111 and the intensity of the scattered light 112 and 113.

In addition to the above, the scattering layer 104 desirably has a configuration in which the intensity of the forward scattered light which is higher than that of the back scattered light with respect to the light 109 which enters at an angle equal to or smaller than the critical angle of the last surface 108. That is, the scattering layer 104 desirably has a configuration in which, among all the light which enters the scattering layer at an angle equal to or smaller than the critical angle on a surface of the scattering layer 104 opposite to the surface which faces the substrate, the intensity of the light scattering toward the substrate is lower than the intensity of the light scattering toward the surface of the opposite side by the scattering layer. Here, the forward scattered light 112 designates the light which reaches the last surface 108 among all the light scattered inside the scattering layer 104, and the back scattered light 113 designates the light which reaches the interface between the scattering layer 104 and the light emitting layer 102 as illustrated in FIG. 2. The light scattered by the scattering layer 104 is distributed to the forward scattered light 112 and the back scattered light 113. A part of the back scattered light 113 transmits the light emitting layer 102 and the front plate 101, is emitted outside, and becomes external reflection light 114. A part of the forward scattered light 112, which is reflected by the last surface 108 and scattered again by the scattering layer 104, transmits the light emitting layer 102 and the front plate 101, is emitted outside, and becomes external reflection light 115. Desirably, the external reflection light of the display device has a uniform orientation intensity distribution. As compared with the back external reflection light 114, the external reflection light 115 has a uniform orientation intensity distribution as a result of the increased number of scattering events caused by the repeated scattering of the forward scattered light 112 by the scattering layer 104. With the intensity of the back scattered light 113 being lower than that of the forward scattered light 112, the orientation intensity distribution of the external reflection light becomes uniform. Therefore, a display device with smaller variation in contrast when seen from an observation direction is achieved.

Desirably, the size of the scatterer included in the scattering layer 104 is smaller than the wavelength of the visible range. A structure as a factor for the production of the scattered light produces is called scatterer. For example, if the fine particles are dispersed with low density in the medium, the fine particles function as a scatterer. If the fine particles are dispersed with high density, the area between fine particles functions as a scatterer. Scattering by a single scatterer is made in the direction different from the incident direction and in a wider angle range, as the scatterer becomes small in size with respect to the wavelength of light. The external light 109 entered from a specific direction is propagated inside the scattering layer 104 while repeating scattering by the single scatterer and propagating to other scatterers. As the orientation intensity distribution of the scattered light of the single scatterer is made uniform, the intensity distribution by multiple scattering in the scattering layer 104 is also made uniform; therefore, the orientation intensity distribution of the external reflection light is made uniform. The size of the scatterer is more desirably equal to or smaller than ½ of the wavelength of visible light and even more desirably equal to or smaller than ⅕ of the wavelength of visible light. If the size of the scatterer is in this range, the scatterability becomes close to the Mie scattering and therefore the orientation intensity distribution may become close to the uniform distribution. With this, the effect described above is further enhanced.

The diameter of the fine particles, the medium and the medium surrounding the fine particles in the light emitting layer 102 and in the scattering layer 104 may be different from one another. Therefore, it is possible to obtain layers having desired scatterability and effective refractive index by appropriately selecting the fine particles, the filling rate and the medium in which the particles are dispersed. With this, the effect described above is enhanced. Scatterability is enhanced when, for example, fine particles of larger diameter are used or the filling rate is reduced. It is only necessary to adjust the effective refractive index in accordance with Equation 1.

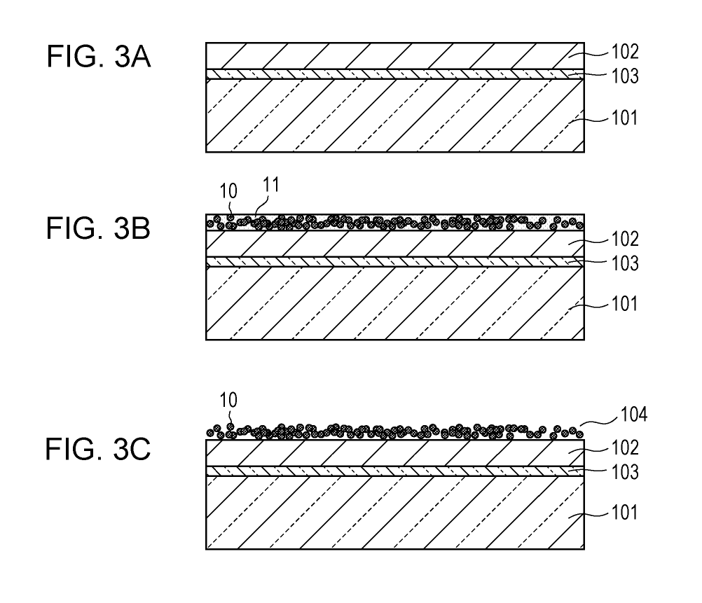

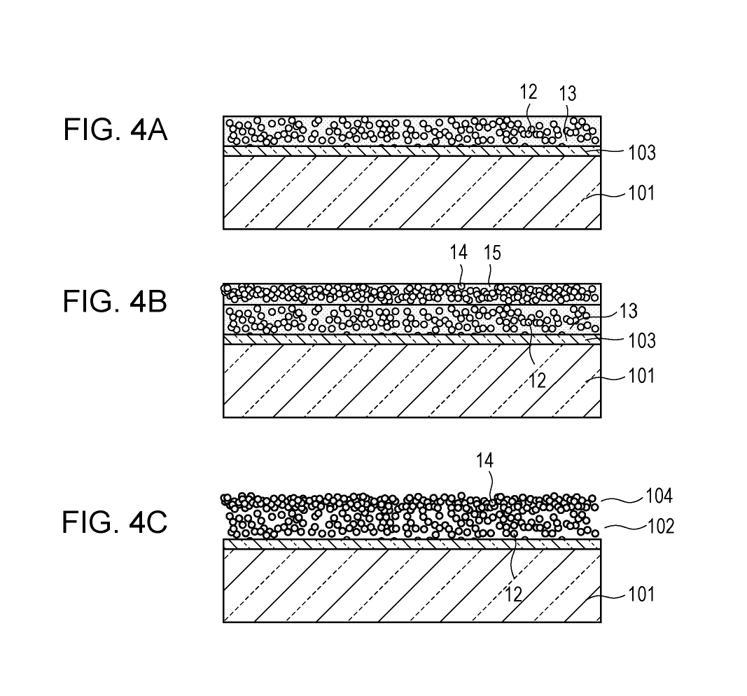

The display device 100 included in the present invention may be manufactured in the processes below. FIGS. 3A to 3C and 4A to 4C illustrate the display device 100 in xy sectional views. The manufacturing process of the electron source 105 is not illustrated.

First, the transparent electrode 103 is formed on the substrate 101. The light emitting layer 102 is formed on the transparent electrode 103 (FIG. 3A). A solution in which the fine particles 10 are dispersed in the solvent 11 is applied as the scattering layer 104. The fine particles 10 may be applied in an inkjet system (FIG. 3B). The applied solution is heated to thereby evaporate the solvent 11. In this manner, the scattering layer 104 is formed.

Alternatively, the transparent electrode 103 is formed on the substrate 101 and, thereon, a solution in which fine particles 12 of the light emitting medium are dispersed in the solvent 13 is applied (FIG. 4A). Then, a solution in which fine particles 14 are dispersed in a solvent 15 is applied onto the light emitting layer 102 (FIG. 4B). The applied solution is heated to evaporate the solvents 13 and 15 to thereby form the light emitting layer 102 and the scattering layer 104 (FIG. 4C). Layers having different effective refractive indices may be produced by using, in the light emitting layer 102 and the scattering layer 104, dispersion liquids in which fine particles different in media and diameter are dispersed therein, or solutions different in density.

The front plate 101 included in the present invention may be formed by a material which is transparent to the visible light, an example thereof being a plastic material. The transparent electrode 103 as a part of the excitation source in the present invention may be provided between the light emitting layer 102 and the scattering layer 104 or on the back side of the scattering layer 104. Further, as described above, the electron source 105 may be provided as a part of the excitation source and may be disposed to face the light emitting layer 102. The excitation source may be formed by an anode and a cathode provided between the front plate 101 and the light emitting layers 102 and on the back side of the light emitting layer 102. When a current is applied between two electrodes and the electrons and the positive holes are injected, light is produced in the light emitting layer 102. Alternatively, the excitation source may be formed in the following manner: an electrode is disposed on the front plate; cells and an electrode are disposed on the back side of the light emitting layer 102; and gas which produces ultraviolet light when plasma is excited is injected in the cells. In such a configuration, when a current is applied to the gas contained in the cells, ultraviolet light is produced; fluorescent substance particles are irradiated with the produced the ultraviolet light and excited. As a result, light is produced.

In the present invention, a layer formed of photonic crystal or a dispersion medium and having a refractive index distribution may be provided between the front plate 101 and the transparent electrode 103. Such a layer is able to convert the light propagating through the light emitting layer 102, the transparent electrode 103 and the scattering layer 104 into the light oriented to a different direction by diffraction or dispersion. With a layer having an appropriate refractive index distribution, the amount of light emitted outside is increased and brightness of the display light is further enhanced.

### EXAMPLES

Hereinafter, examples of the present invention will be described on the basis of the embodiment.

### Example 1

An example of the display device 100 is illustrated in FIG. 1. The front plate 101 is formed by a medium having the refractive index of 1.5. As an excitation source, the transparent electrode 103 formed by a medium having the refractive index of 1.8 is disposed between the light emitting layer 102 and the front plate 101; and the electron source 105 is disposed on the back side of the light emitting layer 102. The light emitting layer 102 is formed by a light emitting medium having the refractive index of 1.5. The scattering layer 104, disposed on the back side of the light emitting layer 102, is a layer in which fine particles having the refractive index of 1.0 and the diameter of 40 nm are dispersed in a medium having the refractive index of 2.2 at the filling rate of 58%. At this time, the effective refractive index of the scattering layer 104 is 1.7. An area on the back side of the scattering layer 104 (i.e., an area between the scattering layer 104 and the electron source 105 and which the back side of the scattering layer 104 opposite to the side which faces the front plate 101 is in contact with) is a vacuum area having the refractive index of about 1. If an electric field is applied to the electron source 105, electrons are emitted and supplied to the light emitting layer 102, thereby producing light. The produced light transmits the front plate 101 and is output to the outside to provide the display light 106.

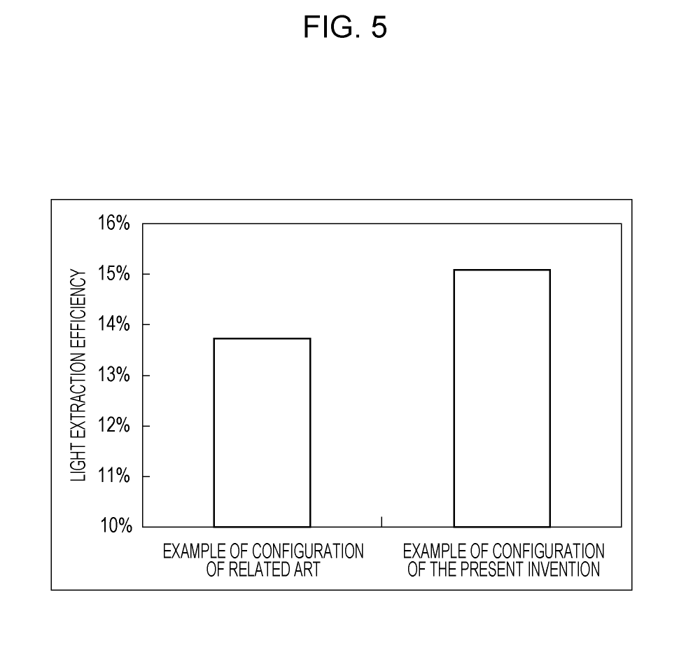

FIG. 5 illustrates a calculation result of light extraction efficiency of the display device 100. FIG. 5 also illustrates light extraction efficiency of a related art configuration which includes no scattering layer 104. As illustrated in FIG. 5, with the scattering layer 104 which reflects the light oriented to the back side of the light emitting layer 102 in the configuration of Example 1, brightness of the display light is enhanced.

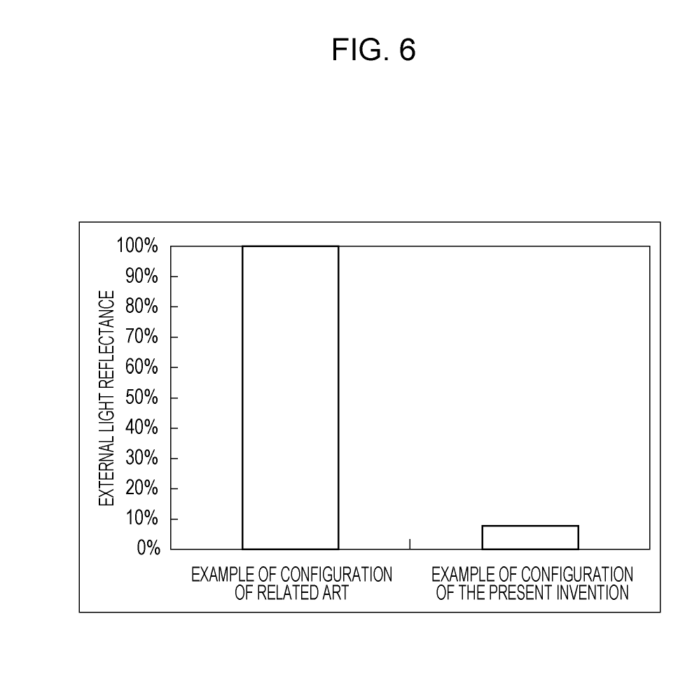

Next, external light is made to enter the display device 100 and the external light reflectance is calculated. The calculation result is illustrated in FIG. 6. FIG. 6 also illustrates reflectance in a related art configuration which includes a metal film on the back side of the light emitting layer 102. FIG. 6 shows that the external light reflectance is decreased in the configuration of Example 1. As described in the embodiment above, the display device 100 of Example 1 includes the scattering layer 104 having the effective refractive index higher than that of the light emitting layer 102 on the back side of the light emitting layer 102. Thus a high contrast display device having high light extraction efficiency and low external light reflectance is achieved.

### Example 2

Another example will be illustrated below. A configuration in this example is the same in the media of the light emitting layer 102 and the scattering layer 104 as those in the example above and different in the filling rate of fine particles. The front plate 101, the electron source 105 and the transparent electrode 103 are the same in configuration as those of the example above. In the light emitting layer 102 and the scattering layer 104, fine particles are dispersed in a medium which has a refractive index different in that of the fine particles. The light emitting layer 102 and the scattering layer 104 are the same in medium and different in filling rate of the fine particles. The light emitting layer 102 is a layer in which fine particles having the refractive index of 1.0 and the diameter of 40 nm are dispersed in a light emitting medium having the refractive index of 2.2 at the filling rate of 41%. At this time, the effective refractive index of the light emitting layer 102 is 1.5. The scattering layer 104 is disposed on the back side of the light emitting layer 102 so as to face the front plate 101 via the light emitting layer 102, and is a layer in which fine particles having the refractive index of 1.0 and the diameter of 40 nm are dispersed in a light emitting medium having the refractive index of 2.2 at the filling rate of 58%. At this time, the effective refractive index of the scattering layer 104 is 1.7. In such a configuration, if an electric field is applied to the electron source, electrons are emitted and supplied to the light emitting layer 102 and the scattering layer 104, thereby producing light. The produced light transmits the front plate 101 and is output to the outside to provide the display light 106.

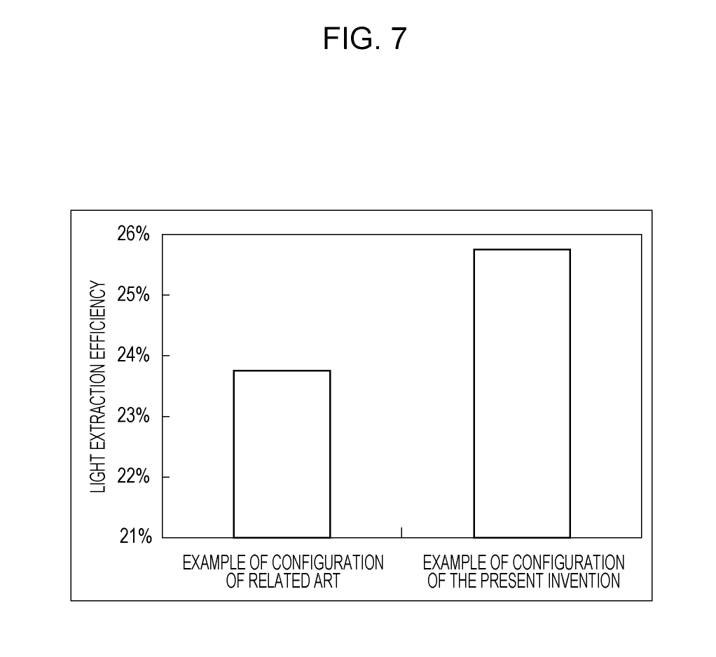

FIG. 7 illustrates a calculation result of light extraction efficiency of the display device 100 of Example 2 described above. FIG. 7 also illustrates light extraction efficiency of a configuration which includes no scattering layer 104. As illustrated in FIG. 7, with the scattering layer 104 which reflects the light oriented to the back side of the light emitting layer 102 in the configuration of Example 2, brightness of the display light is enhanced similarly to the example described above.

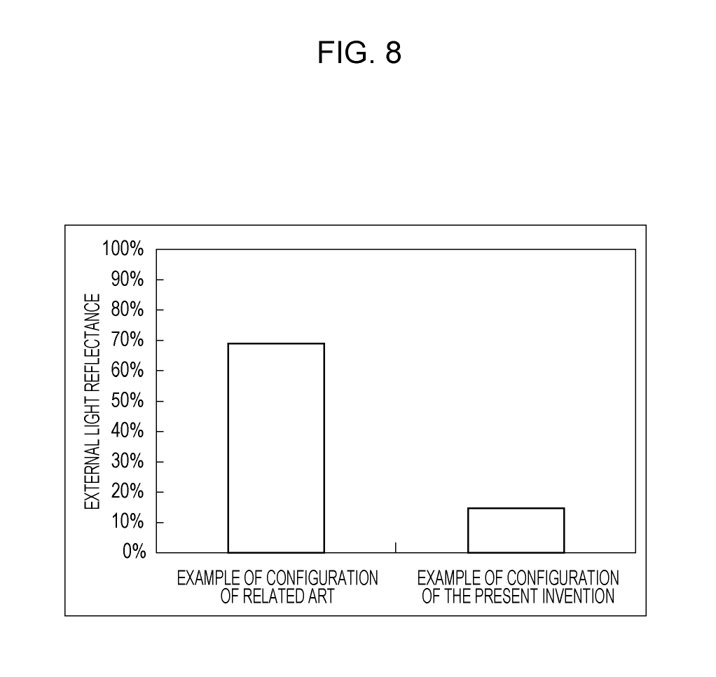

Next, external light is made to enter the display device 100 and the external light reflectance is calculated. The calculation result is illustrated in FIG. 8. FIG. 8 also illustrates reflectance in a related art configuration (Comparative Example) which includes no scattering layer 104 but includes a metal film on the back side of the light emitting layer 102. FIG. 8 shows that the external light reflectance is decreased in the configuration of Example 2 similarly to that of Example 1. Similarly to Example 1, with the display device 100 of Example 2 in which the light emitting layer 102 and the scattering layer 104 are the same in medium and different in filling rate of the fine particles and thereby having different effective refractive indices, a high contrast display device having high light extraction efficiency and low external light reflectance is achieved.

Configurations and media of each of the areas are not restricted to those illustrated in Examples.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-290329 filed Dec. 27, 2010, which is hereby incorporated by reference herein in its entirety.

What is claimed is:

1. A display device comprising:
a substrate;
a light emitting layer disposed on the substrate; and
a scattering layer which is disposed on the substrate via the light emitting layer to face the substrate and scatters at least a part of light produced by the light emitting layer,
wherein:
an effective refractive index of the light emitting layer is higher than a refractive index of an area which a surface of the scattering layer opposite to a surface which faces the substrate is in contact with; and
an effective refractive index of the scattering layer is higher than the effective refractive index of the light emitting layer.

2. The display device according to claim 1, wherein the scattering layer is formed by a nonmetallic member.

3. The display device according to claim 1, wherein the scattering layer includes a medium and fine particles dispersed in the medium.

4. The display device according to claim 3, wherein the fine particles are formed by a light emitting material.

5. The display device according to claim 3, wherein a diameter of each of the fine particles is equal to or smaller than a wavelength of visible light.

6. The display device according to claim 3, wherein the light emitting layer includes a medium and fine particles dispersed in the medium.

7. The display device according to claim 6, wherein the medium and the fine particles included in the light emitting layer are the same as the medium and the fine particles included in the scattering layer.

8. The display device according to claim 7, wherein a filling rate of the fine particles included in the light emitting layer in the medium included in the light emitting layer is different from a filling rate of the fine particles included in the scattering layer in the medium included in the scattering layer.

9. The display device according to claim 1, wherein the scattering layer has a configuration in which, among all light which enters the scattering layer at an angle equal to or smaller than a critical angle on a surface of the scattering layer opposite to a surface which faces the light emitting layer, an intensity of the light which is not scattered by the scattering layer but is reflected toward the substrate is lower than a sum of the intensity of light which is not scattered by the scattering layer but transmitted by the scattering layer and an intensity of light scattered by the scattering layer.

10. The display device according to claim 1, wherein the scattering layer has a configuration in which, among all light which enters the scattering layer at an angle equal to or smaller than a critical angle on a surface of the scattering layer opposite to a surface which faces the light emitting layer, an intensity of the light scattering toward the substrate is lower than an intensity of the light scattering toward a surface of an opposite side by the scattering layer.
